(19) United States
(12) Patent Application Publication
(10) Pub. No.: US 2016/0053069 A1
(43) Pub. Date: Feb. 25, 2016

(54) SILICONE RESIN FOAM AND SEALING MATERIAL

(71) Applicant: SEKISUI CHEMICAL CO., LTD., Osaka-shi, Osaka (JP)

(72) Inventors: Masahiko GOTOH, Osaka (JP); Kouzou NAKAMURA, Osaka-shi, Osaka (JP)

(73) Assignee: SEKISUI CHEMICAL CO., LTD., Osaka (JP)

(21) Appl. No.: 14/779,608

(22) PCT Filed: Mar. 26, 2014
(86) PCT No.: PCT/JP2014/058701

§ 371 Date: Sep. 24, 2015

(30) Foreign Application Priority Data
Mar. 27, 2013 (JP) 2013-067255
Sep. 30, 2013 (JP) 2013-205462

(51) Int. Cl. C08J 9/228; H01L 31/048; B32B 5/18

(52) U.S. Cl. CPC C08J 9/228; B32B 5/18; H01L 31/0481; C08J 2319/00; B32B 2581/00; B32B 25/20

(57) ABSTRACT

A silicone resin foamed body according to the present invention comprises: a silicone resin cured product (A); and a plurality of particles (B) dispersed in the silicone resin cured product (A) and each having a cavity portion (b1) therein, wherein the silicone resin foamed body has a cavity portion (C) surrounded with the silicone resin cured product (A) or with the silicone resin cured product (A) and the particles (B) in the silicone resin cured product (A).

### TECHNICAL FIELD

The present invention relates to a foamed body formed of a silicone resin, and a sealing material preferably used for a solar cell.

### BACKGROUND ART

Conventionally, as foamed bodies, foamed bodies in which chemical foaming agents are utilized, foamed bodies in which hollow particles are utilized, foamed bodies that are foamed by hydrogen gas released during crosslinking reactions, and foamed bodies that are foamed by supercritical gas foaming, have been known (for example, see Patent Literatures 1 to 4).

Moreover, it has also been known that foamed bodies have been used as sealing materials in solar cell-related fields. Such a sealing material used for a solar cell is disposed between the peripheral end portion of a panel and a support frame material and prevents the entry of water and the like into the panel, when the peripheral end portion of the solar cell panel is fixed to the support frame member, for example. As such a solar cell sealing material, foamed bodies obtained by foaming rubbers such as EPDMs with foaming agents such as azodicarbonamide, acrylic foamed bodies, and the like are conventionally used (for example, see Patent Literatures 5 and 6).

However, it is desired that sealing materials used for solar cells exhibit high shock absorbency and sealing properties even if the thickness is small. In addition, since solar cells are installed and used outdoors for a long period, it is desired that the sealing materials have high cold and heat resistance and light resistance so that performance is maintained even if temperature changes due to a difference in temperature between day and night or between the four seasons occur. However, such sealing materials used for solar cells that exhibit excellent shock absorbency, sealing properties, cold and heat resistance, and light resistance, even if the thickness is small, might have not been known yet.

On the other hand, as a material having high cold and heat resistance and high light resistance, a silicone resin is widely known.

### CITATION LIST

### Patent Literature

PTL1: Japanese Patent Laid-Open No. 2008-214439

PTL2: Japanese Patent No. 3274487

PTL3: Japanese Patent Publication No. 5-15729

PTL4: Japanese Patent Laid-Open No. 9-77898

PTL5: Japanese Patent Laid-Open No. 2009-71233

PTL6: Japanese Patent Laid-Open No. 2012-1707

### SUMMARY OF INVENTION

### Technical Problem

However, it is difficult to manufacture a foamed body composed of a silicone resin that has high shock absorbency and sealing properties even if the thickness is small.

For example, as described in Patent Literatures 1, 3 and 4, when a foamed body of a silicone resin is formed by generating gas inside the resin, the distance between the gas generation site and the external space becomes short in the case of the small thickness of the sheet, and thereby, a large amount of gas is released to the external space due to the silicone resin having the high gas permeability. As a result, the amount of gas remaining in the silicone resin is decreased, and therefore, the expansion ratio cannot be sufficiently increased.

Moreover, as described in Patent Literature 2, when a foamed body is formed using hollow particles, if the hollow particles is made to be small, the volume of the outer shells of the hollow particles increases, so that the expansion ratio cannot be sufficiently improved. Furthermore, if the size of a hollow particle is increased in the case of the small thickness of a foamed body, a large amount of hollow particles cannot be blended. Therefore, in the case of a foamed body whose thickness is small, it has been difficult to improve the expansion ratio, regardless of the size of a hollow particle. It is to be noted that, if the thickness of the outer shell of a hollow particle were decreased to minimum, it would be theoretically possible to increase the expansion ratio. In reality, however, since hollow particles are destroyed during a step of forming a foamed body, such as a roll molding step or a press step, it would be impractical.

As mentioned above, it is difficult to achieve a high expansion ratio in a silicone resin foamed body having a small thickness such as 2.5 mm or less, for example.

The present invention has been made in view of the above problems, and it is an object of the present invention to provide a foamed body that achieves a high expansion ratio and has excellent shock absorbency, sealing properties, cold and heat resistance, and light resistance in any thicknesses, even in the case of small thickness.

### Solution to Problem

As a result of diligent study, the present inventors have found that by dispersing a plurality of particles each having a cavity portion therein in a silicone resin to make the cavity portions the cells of a foamed body, and also by keeping a void between the particles as a cavity without filling the void with a silicone resin, a silicone resin foamed body having a high expansion ratio can be manufactured. Moreover, the inventors have also found that a silicone resin foamed body itself and a laminated body formed by further laminating a film on the foamed body have good shock absorbency, sealing properties, cold and heat resistance, and light resistance even if the thickness is small, and are useful for solar cells, thus completing the present invention below.

Specifically, the present invention provides the following (1) to (7).
(1) A silicone resin foamed body comprising: a silicone resin cured product (A) formed by curing a silicone resin composition; and a plurality of particles (B) dispersed in the silicone resin cured product (A) and each having a cavity portion (b1) therein, wherein the silicone resin foamed body has a cavity portion (C) surrounded with the silicone resin cured product (A) or with the silicone resin cured product (A) and the particles (B) in the silicone resin cured product (A), and the volume ratio of the cavity portion (b1) to the cavity portion (C) is 2:1 to 1:4. (2) The silicone resin foamed body according to the above (1), which is obtained by curing a mixture comprising the silicone resin composition and the plurality of particles (B), a space around the particles (B) being present in the mixture, wherein the cavity portion (C) is formed by the space.
(3) The silicone resin foamed body according to the above (1) or (2), wherein the cavity portion (C) is not formed using a chemical foaming agent.
(4) The silicone resin foamed body according to any one of the above (1) to (3), having a thickness of 0.05 to 2.5 mm and an expansion ratio of 7 cc/g or more.
(5) The silicone resin foamed body according to any one of the above (1) to (4), wherein the plurality of particles (B) comprise foamed particles that have been expanded.
(6) A sealing material comprising: the silicone resin foamed body according to any one of the above (1) to (5); and a film (E) and/or a pressure-sensitive adhesive layer (F) that are laminated on the silicone resin foamed body.
(7) A method for manufacturing the silicone resin foamed body according to any one of the above (1) to (5), comprising: a step of obtaining a mixture of particles (B) each having a cavity portion (b1) therein and a silicone resin composition, a space being present around the particles (B) in the mixture; and a step of curing the mixture to obtain a silicone resin foamed body.

### Advantageous Effects of Invention

According to the present invention, it is possible to provide a foamed body that has a high expansion ratio and also has excellent shock absorbency, sealing properties, cold and heat resistance, light resistance, and the like, in any thicknesses, even in the case of the small thickness of the foamed body.

### BRIEF DESCRIPTION OF DRAWINGS

FIG. 1 is a schematic view showing a mixture containing particles before foaming in Step 1.

FIG. 2 is a schematic view showing a mixture containing particles after foaming.

### DESCRIPTION OF EMBODIMENTS

The present invention will be described in more detail below with reference to embodiments.

### (Silicone Resin Foamed Body)

A silicone resin foamed body of the present invention comprises a silicone resin cured product (A) formed by curing a silicone resin composition and a plurality of particles (B) dispersed in the silicone resin cured product (A) and each having a cavity portion (b1) therein, and specifically, the silicone resin foamed body of the present invention is formed by curing a resin-particle mixture in which the plurality of particles (B) are dispersed in the silicone resin composition.

In addition, in the silicone resin foamed body of the present invention, a cavity portion (C) that is different from the cavity portion (b1) in each of the particles (B) is present in the silicone resin cured product (A), as described later.

### [Silicon Resin Cured Product (A)]

The silicone resin cured product (A) is obtained by curing a silicone resin composition having curability. The silicone resin composition is preferably a two-part liquid and addition-reaction type silicone resin composition.

The silicone resin composition comprises, for example, an organopolysiloxane (x) having at least two alkenyl groups in one molecule, an organohydrogenpolysiloxane (y) having at least two hydrogen atoms that are bonded to a silicon atom in one molecule, and a platinum-based catalyst (z).

In the silicone resin composition, the (y) component and the (z) component are mixed in the (x) component which is used as a base resin so that a curing reaction is started, and then the reaction is promoted, for example, under high-temperature conditions.

Accordingly, in the case of the two-part liquid and addition-reaction type silicone resin composition, a liquid comprising the (x) component and the (y) component may be used as the first liquid, and a liquid comprising the (z) component may be used as the second liquid. Alternatively, a liquid comprising the (x) component and the (z) component may be used as the first liquid, and a liquid comprising the (y) component may be used as the second liquid.

The organopolysiloxane that is the (x) component constitutes a base resin for the silicone resin composition and has at least two alkenyl groups that are bonded to a silicon atom. As the alkenyl group, a vinyl group, an allyl group, and the like are illustrated. In addition, examples of the organic groups bonded to the silicon atoms other than the alkenyl groups include alkyl groups having 1 to 3 carbon atoms such as a methyl group, an ethyl group, and a propyl group; aryl groups such as a phenyl group and a tolyl group; and substituted alkyl groups such as a 3,3,3-trifluoropropyl group and a 3-chloropropyl group. The molecular structure of the (x) component may be either linear or branched.

The molecular weight of the (x) component (namely, a base resin) is not particularly limited, but the viscosity at 23° C. thereof is preferably 20 Pa·s or less, more preferably 0.1 to 15 Pa·s, and further preferably 2.5 to 8 Pa·s. In the present invention, two or more kinds of the above organopolysiloxanes may be used in combination.

Moreover, in the present invention, by setting the viscosity of the (x) component (namely, a base resin) to 8 Pa·s or less, a cavity portion (b1) and a space serving as a cavity portion (C) later can be easily formed when the particles are foamed after mixing silicone resin composition and the particles (B), as described later.

It is to be noted that the viscosity is measured using a capillary viscometer according to JIS Z8803.

The organohydrogenpolysiloxane that is the (y) component constitutes a curing agent, and the silicon atom-bonded hydrogen atoms of the (y) component undergo an addition reaction with the silicon atom-bonded alkenyl groups of the organopolysiloxane in the (x) component in the presence of the platinum-based catalyst that is the (z) component, to crosslink and cure the curable silicone resin composition. The (y) component needs to have at least two hydrogen atoms that are bonded to a silicon atom in one molecule. In the (y) component, examples of the organic groups bonded to the silicon atoms include alkyl groups having 1 to 3 carbon atoms such as a methyl group, an ethyl group, and a propyl group; aryl groups such as a phenyl group and a tolyl group; and halogen atom-substituted alkyl groups such as a 3,3,3-trifluoropropyl group and a 3-chloropropyl group. The molecular structure of the (y) component may be any of linear, branched, cyclic, and network structures.

The molecular weight of the (y) component is not particularly limited, but the viscosity at 23° C. thereof is preferably 0.005 to 8 Pa·s, and more preferably 0.01 to 4 Pa·s.

The amount of the (y) component added is determined such that the molar ratio of the hydrogen atoms bonded to a silicon atom in this component to the alkenyl groups bonded to a silicon atom in the (x) component is (0.5:1) to (20:1), and the molar ratio is preferably in the range of (1:1) to (3:1). When this molar ratio is 0.5 or more, the curability is relatively good, and when this molar ratio is 20 or less, the hardness of the silicone resin foamed body is of suitable magnitude.

The platinum-based catalyst that is the (z) component is used for curing the silicone resin composition. As the platinum-based catalyst, platinum fine powders, platinum black, chloroplatinic acid such as hexachloroplatinic acid, platinum tetrachloride, olefin complexes of chloroplatinic acid, such as tetraammineplatinum chloride, alcohol solutions of chloroplatinic acid, complex compounds of chloroplatinic acid and alkenylsiloxanes, rhodium compounds, palladium compounds, and the like are illustrated. In addition, in order to increase the pot life of the silicone resin composition, thermoplastic resin particles containing these platinum-based catalysts may be used.

The amount of this platinum-based catalyst added is usually 0.1 to 500 parts by weight, and preferably in the range of 1 to 50 parts by weight, as a platinum-based metal, based on 1,000,000 parts by weight of the (x) component. By setting the amount of the platinum-based catalyst added to 0.1 parts by weight or more, the addition reaction can proceed suitably. By setting the amount of the platinum-based catalyst added to 500 parts by weight or less, the present invention can be carried out economically.

Examples of commercial products of the silicone resin composition include the two-component heat-curable liquid silicone rubber “TSE3032” manufactured by Momentive Performance Materials Japan LLC.

[Plurality of Particles (B)]

The average particle diameter of the particles (B) may differ depending on the thickness of the silicone resin foamed body, but is preferably 5 μm or more, more preferably 10 μm or more, and further preferably 20 μm or more, and is preferably 300 μm or less, more preferably 150 μm or less, and further preferably 120 μm or less. By setting the average particle diameter to 300 μm or less, closed cells are formed by the particles (B) and the silicone resin foamed body can function as a sealing material even if the silicone resin foamed body is extremely thin. In addition, by setting the average particle diameter to 5 μm or more, the shock resistance and the sealing properties can be made to be good.

The plurality of particles (B) are dispersed in the silicone resin foamed body (A), and each has a cavity portion therein. The plurality of particles (B) may show different particle diameter distributions, or may show a single particle diameter distribution.

“Showing different distributions” means that two or more peaks are present when the particle diameters of, for example, 100 particles (B) are measured by a method described later and a particle distribution graph is prepared. “Showing three types of particle diameter distributions” means that three peaks are present.

Examples of the shape of the particles (B) include a spherical shape, a plate shape, a needle shape, and an irregular shape. From the viewpoint of still further increasing the filling properties and dispersibility of the particles (B), the particles (B) are preferably spherical. The aspect ratio of the spherical particles is 5 or less, preferably 2 or less, and more preferably 1.2 or less.

The average particle diameter herein is the average value of measured values when the sizes of the primary particles of 100 particles in an observed field of view are measured using a scanning electron microscope, an optical microscope, or the like. When the above particles are spherical, the average particle diameter means the average value of the diameters of the particles. When the above particles are nonspherical, the average particle diameter means the average value of the major axes of the particles. In addition, the aspect ratio is represented by the ratio of the major axis to the minor axis (the average value of the major axes/the average value of the minor axes).

The particles (B) are so-called hollow particles each having an outer shell in which a cavity portion (b1) is present. The particles (B) each preferably have one cavity portion therein. The particles (B) are preferably organic particles, that is, the material of the outer shells of the particles (B) is preferably an organic compound.

The void ratio of the particles (B) is preferably 50% or more, more preferably 80% or more, and further preferably 90% or more, and is preferably 98% or less, more preferably 97% or less, and further preferably 96% or less. When the above void ratio is 50% or more, the shock absorption resistance, sealing properties, and flexibility of the sealing material increase. When the above void ratio is set to 80% or more or 90% or more, the shock absorption resistance, sealing properties, and flexibility of the sealing material increase still further. When the above void ratio is 98% or less, the strength of the particles (B) increases, and the outer shells do not crack easily. When the above void ratio is set to 97% or less or 96% or less, the strength increases still further.

The void ratio herein means a volume ratio that represents the volume of the void portions in the total volume of the above particles (B) by percentage (%). Specifically, for example, 100 particles are arbitrarily extracted from a photograph taken by a microscope, and the major and minor axes of the particle outer diameters, and the major and minor axes of the particle void portions are measured. Then, the void ratio of each particle is calculated by the following formula, and the average value of the void ratios of the 100 particles is taken as the void ratio of the particles (B).

Void ratio (% by volume)=((Void portion major axis+Void portion minor axis)/(Major axis of the outer diameter+Minor axis of the outer diameter))³×100

The particles (B) are preferably hollow particles formed by expanding foamable particles (B₁). In the present invention, by the use of the foamable particles (B₁), the shock resistance performance and flexibility of the silicone resin foamed body increase still further, and the thickness of the silicone resin foamed body can be decreased. Moreover, since the thickness of the outer shell of a hollow particle can be decreased, for that the expansion ratio of the foamed body can be increased.

The above foamable particles (B₁) are more preferably thermally-expandable microcapsules having thermal foamability that they are foamed and expanded by heating. The thermally-expandable microcapsules contain a volatile substance such as a low boiling point solvent encapsulated by an outer shell resin thereof. By heating, the outer shell resin softens, and the contained volatile substance volatilizes or expands, and therefore, the outer shells expand due to the pressure, and the particle diameters increase to form hollow particles. The temperature at which the thermally-expandable microcapsules are foamed is not particularly limited but is preferably greater than foam start temperature and less than maximum foam temperature described later.

The outer shells of the thermally-expandable microcapsules are preferably formed of a thermoplastic resin. For the thermoplastic resin, one or more selected from vinyl polymers of ethylene, styrene, vinyl acetate, vinyl chloride, vinylidene chloride, acrylonitrile, methacrylonitrile, butadiene, chloroprene, or the like and copolymers thereof; polyamides such as nylon 6 and nylon 66; and polyesters such as polyethylene terephthalate can be used. Copolymers of acrylonitrile are preferred, since the contained volatile substance therein does not easily pass through them. As the volatile substance contained in the thermally-expandable microcapsules, one or more low boiling point liquids selected from hydrocarbons having 3 to 8 carbon atoms such as propane, propylene, butene, normal butane, isobutane, isopentane, neopentane, normal pentane, hexane, heptane, octane, and isooctane; petroleum ether; halides of methane such as methyl chloride and methylene chloride; chlorofluorocarbons such as CCl₃F and CC₂F₂; tetraalkylsilanes such as tetramethylsilane and trimethylethylsilane; and the like are used.

Preferred examples of the thermally-expandable microcapsules include microcapsules which comprise, as an outer shell resin, a copolymer of acrylonitrile, methacrylonitrile, vinylidene chloride or the like that is a main component, and which also contain a hydrocarbon having 3 to 8 carbon atoms such as isobutane therein.

The thermally-expandable microcapsules before foaming have an average particle diameter of preferably 1 μm or more, more preferably 4 μm or more, and preferably less than 50 μm, more preferably less than 40 μm. By setting the average particle diameter to the above lower limit value or more, the aggregation of the particles is not easily caused, and the thermally-expandable microcapsules are easily uniformly dispersed in the resin. In addition, by setting the average particle diameter to the upper limit value or less, a decrease in the number of cells in the thickness direction and an increase in the size of the cells are prevented when a foamed body is formed, and quality such as mechanical properties can be stabilized.

In addition, the foamable particles (B₁) such as the thermally-expandable microcapsules preferably expand so that the average particle diameter preferably increases 2 times or more and 10 times or less, to form the above particles (B). In addition, the foam start temperature of the foamable particles such as the thermally-expandable microcapsules is preferably 95 to 150° C., and further preferably 105 to 140° C. In addition, the maximum foam temperature is preferably 120 to 200° C., and further preferably 135 to 180° C.

Examples of commercial products of the thermally-expandable microcapsules include “EXPANCEL” manufactured by Japan Fillite Co., Ltd., “ADVANCELL” manufactured by SEKISUI CHEMICAL CO., LTD., “Matsumoto Microsphere” manufactured by Matsumoto Yushi-Seiyaku Co., Ltd., and “Microsphere” manufactured by KUREHA CORPORATION.

In the present invention, preferably 0.1 part by mass or more, more preferably 1 part by mass or more, and preferably 30 parts by mass or less, more preferably 10 parts by mass or less, of foamable particles that is unfoamed, which are used for forming the particles (B) each having a cavity portion therein, are contained based on 100 parts by mass of a silicone resin composition.

When the content of the foamable particles is set to the above lower limit or more and the above upper limit or less, the sealing properties and shock absorbency of the silicone resin foamed body and the sheet strength increase with a good balance.

The silicone resin foamed body of the present invention may further contain particles (D) dispersed in the silicone resin cured product (A) and each having no cavity portion therein, in addition to the particles (B). The particles (D) may be any of inorganic particles, organic particles, and organic-inorganic composite particles.

Examples of the particles (D) include inorganic particles composed of one or more inorganic compounds selected from alumina, synthetic magnesite, silica, boron nitride, aluminum nitride, silicone nitride, silicone carbide, zinc oxide, magnesium oxide, talc, mica, and hydrotalcite. Both inorganic particles and organic particles may be used.

[Other Components]

The resin-particle mixture for forming the silicone resin foamed body may further comprise various additives such as a coupling agent, a dispersing agent, an antioxidant, an antifoaming agent, a coloring agent, a modifying agent, a viscosity-adjusting agent, a light-diffusing agent, a curing inhibitor, and a flame retardant, as required. Examples of the above coloring agent include pigments. Examples of the above viscosity-adjusting agent include silicone oils.

[Cavity Portion (C)]

The silicone resin foamed body of the present invention further has a cavity portion (C), other than the cavity portion (b1) contained in each of the particles (B). The cavity portion (C) is a cavity portion surrounded with the silicone resin cured product (A), or with the silicone resin cured product (A) and the particles (B), and the cavity portion (C) is present in the silicone resin cured product (A). In addition, when the silicone resin foamed body of the present invention also contain the particles (D), the cavity portion (C) may comprise a cavity portion that is surrounded with the silicone resin cured product (A) and/or the particles (B) and with the particles (D).

Although it is difficult to sufficiently increase the expansion ratio only by the cavity portion (b1) contained in each of hollow particles, the expansion ratio can be sufficiently increased with the cavity portion (C) in the present invention.

Moreover, the cavity portion (C) is preferably formed by air that has been mixed as gas from the outside to the resin-particle mixture for forming the foamed body, as described later.

That is to say, the cavity portion (C) of the present invention is preferably not formed by foaming with a foaming agent such as a chemical foaming agent, other than the particles (B) that is blended in the resin-particle mixture. Thereby, no foaming agents need to be foamed other than the foaming (expansion) of the particles (B), and thus, the achievement of high expansion ratio and simplification of the processes become possible. That is, if the particles (B) and the foaming agent are simultaneously foamed, they inhibit their foaming with each other, and it becomes difficult to achieve high expansion ratio. On the other hand, if the particles (B) and the foaming agent are foamed with different timing, the processes become complicated. However, the present invention does not cause such problems.

Furthermore, the difficulty in achieving high expansion ratio, owing to releasing foamed gas to the external space during the foaming of a foaming agent, is not caused. Further, in the present invention, by no use of foaming agents other than the particles (B), the amount of a foamed residue that is generated as a result of the foaming and destruction of a foaming agent such as a chemical foaming agent can be decreased.

It is to be noted that the term “chemical foaming agent” is used in the present invention to mean an agent that generates gas as a result of a chemical reaction and directly forms cells with such gas in a resin composition. Thus, a microcapsule that contains a foaming agent encapsulated by the outer shell thereof and is capable of forming a cell (cavity portion (b1)) in each particle, and the like are not included in the chemical foaming agent.

[Volume Ratio of Cavity Portion (b1) to Cavity Portion (C)]

In the silicone resin foamed body of the present invention, the volume ratio (b1:C) of the cavity portion (b1) to the cavity portion (C) is 2:1 to 1:4. If the volume ratio is out of this range, the expansion ratio of the silicone resin foamed body cannot be sufficiently increased, or there is a possibility that the foamed body is not able to be easily manufactured. From such a viewpoint, the volume ratio (b1:C) is preferably 1:1 to 1:2.

### [Thickness of Silicone Resin Foamed Body]

The silicone resin foamed body has a thickness of preferably 0.05 mm or more and preferably 2.5 m or less. In the present invention, by setting the thickness to 0.05 mm or more, high shock absorption performance and sealing properties can be ensured when the silicone resin foamed body is used as a sealing material. In addition, by setting the thickness to 2.5 m or less, the thinning of a solar cell panel or a mobile phone as described later, the size reduction and weight reduction of various vehicle parts in internal combustion engines, their peripherals, or the like are possible. Moreover, the thickness is more preferably 0.1 mm or more, and more preferably 1 mm or less.

### [Expansion Ratio of Silicone Resin Foamed Body]

In the present invention, the expansion ratio of the silicone resin foamed body is preferably 7 cc/g or more. The upper limit is not particularly limited, but when the silicone resin foamed body is used as a sealing material, the expansion ratio is preferably 20 cc/g or less. By setting the expansion ratio within the above range, when the silicone resin foamed body is used as a sealing material, shock absorbency, sealing properties, and flexibility can be improved.

Moreover, in the case of a silicone resin foamed body having a small thickness of 2.5 mm or less, although it has been difficult to obtain an expansion ratio of 5 cc/g or more only by the cavity portion (b1) contained in each of the particles (B), it becomes easily possible to obtain an expansion ratio of 7 cc/g or more by providing the cavity portion (C) in the present invention. Furthermore, by setting the expansion ratio to the above upper limit or less, the closed cell ratio can be made to be in an appropriate range, and also, the strength of the silicone resin foamed body can be made to be good.

[Closed Cell Ratio]

In the silicone resin foamed body of the present invention, the cavity portion (b1) in each of the particles (B) is usually a closed cell. On the other hand, the cavity portion (C) is either a closed cell or an open cell.

In the silicone resin foamed body, the ratio of closed cells to the total cells (which is referred to as a “closed cell ratio”) is preferably 65% or more, more preferably 75% or more, and most preferably 80% or more. In the present invention, the particles (B) are hollow particles, and further, the silicone resin foamed body is preferably obtained by curing a silicone resin composition containing foamed particles that have previously been foamed. Due to these, the closed cell ratio can be increased.

The closed cell ratio can be obtained according to JIS K7138 (2006).

### [Method for Manufacturing Silicone Resin Foamed Body]

The method for manufacturing a silicone resin foamed body of the present invention comprises: forming a space (C₁) other than a cavity portion (b1) contained in each of particles (B) in a resin-particle mixture; and then curing the resin-particle mixture to produce a foamed body having high expansion ratio even having a small thickness.

A method for manufacturing a silicone resin foamed body according to one embodiment of the present invention comprises the following Step 1 to Step 4.

### (Step 1)

In the present Step 1, first, a plurality of unfoamed foamable particles (B₁), such as expandable microcapsules, are foamed, so as to obtain particles (B) each having a cavity portion (b1) therein. At this time, it is preferable that the unfoamed foamable particles are added to a base resin (x) of a silicone resin composition and then the resultant mixture is heated, so that the unfoamed foamable particles are expanded. Specifically, the following operations are preferably carried out. That is, the unfoamed foamable particles are added to the base resin (x), and they are then mixed by stirring with a planetary mixer, a three-roll mill, or the like. Subsequently, the resultant mixture is placed on a stainless steel belt or a PET film by being thinly applied thereon or the like, and it is then heated in a heating furnace or the like, so that foamable particles are expanded.

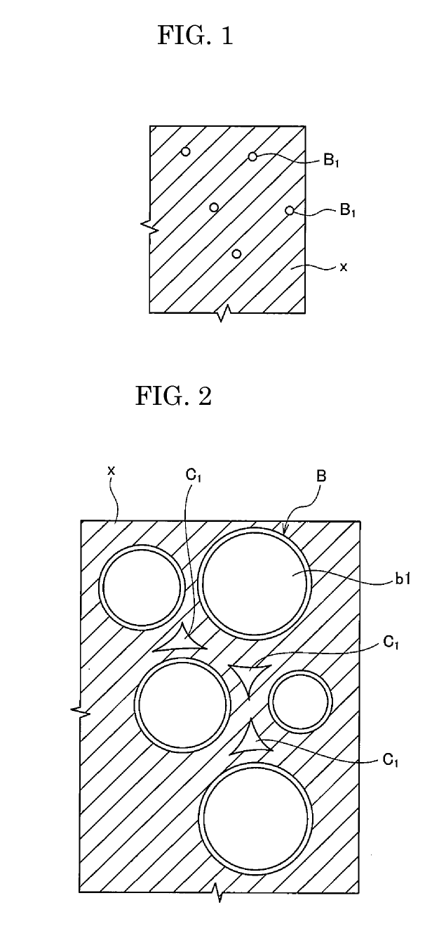

FIG. 1 is a schematic view showing a mixture of the foamable particles (B₁) and the base resin (x) before thermal expansion in the present Step 1. As shown in FIG. 1, before the foaming of the foamable particles (B₁), in the mixture of the base resin (x) of a silicone resin composition and the foamable particles (B₁), the space (C₁) described later is not generally formed.

FIG. 2 is a schematic view showing a mixture obtained after the foamable particles are heated and expanded. In the mixture of the base resin (x) of the silicone resin composition and the particles (B) that have been foamed, obtained in the present Step 1, as shown in FIG. 2, by the external air, a space (C₁) is formed in the base resin (x) around the particles (B) whose diameter has been increased. This space (C₁) becomes a cavity portion (C) later, and in other words, the cavity portion (C) is formed by incorporation of the external air.

It is assumed that the space (C₁) will be formed as follows. In Step 1, when the foamable particles (B₁) are expanded, the mixture is greatly expanded by 15- to 75-fold in appearance, and upon the expansion, the base resin (x) often adheres to the outer circumference of each of the foamable particles (B₁), and gas is released from the foamable particles (B₁). By such phenomena, spaces (C₁) can be formed by the released gas in the base resins (x) among a plurality of the foamable particles (B₁). The gas in the space (C₁), namely in the cavity portion (C) is then replaced with the external air, and as a result, it is considered that the space (C₁) is formed by air incorporated from the outside.

There is a possibility that unfoamed foamable particles would be attached to one another after completion of the expansion if they are expanded alone, but the particles can be foamed without causing the attachment due to mixing the unfoamed foamable particles with the base resin of a silicone resin composition in the present invention.

In addition, upon foaming, if the viscosity of the base resin of a silicone resin composition is high, foamability would be impaired. Thus, it is desired that the viscosity of the base resin of a silicone resin composition is low as described above. As the expansion ratio of the particles (B) themselves increases, the size of the spaces (C₁) that are formed around particles (B) and that will then become cavity portions (C) also increases, and thus, the expansion ratio also increases. Needless to say, if the expansion ratio of the particles (B) is high, the final expansion ratio will be naturally high. Moreover, the base resin is mixed with particles, dividedly in Step 1 and Step 2, but in Step 1, the mass ratio of the weight of expandable microcapsules to the base resin (namely, a silicone resin composition added in Step 1) is preferably 2:1 to 1:20. In a case where the expandable microcapsules are mixed beyond the aforementioned range, there is a possibility that the particles would be attached to one another after completion of the expansion. In a case where it is below the aforementioned range, the distance between particles after expansion increases, spaces (C₁) are hardly formed, and thus, cavity portions (C) might not be formed. A more preferred range of the above mass ratio is 1:5 to 1:15.

Moreover, a component which unfoamed particles are mixed with in Step 1 may be a component of the silicone resin composition, other than the base resin, such as a curing agent of a silicone resin composition, as long as the selected components do not significantly inhibit the foamability and can form spaces (C₁).

### (Step 2)

Next, the particles (B) that have been mixed with the base resin or the other of a silicone resin composition in Step 1 are mixed with the remaining silicone resin composition and other components such as particles (D), so as to prepare a resin-particle mixture. If a space is formed in a composition, for example, by the gas of foamable particles, since the formed space is an unnecessary void for design in general, it is generally considered that the space would be intended to be eliminated by mixing, stirring, compression, or the like. However, in the present Step 2, the components are mixed without eliminating the spaces (C₁) formed in the above Step 1, so as to prepare the resin-particle mixture.

When the base resin and the curing agent for the resin-particle mixture are uniformly mixed, a space that is formed in the Step 1 and that will be a cavity portion (C) becomes smaller, as the mixing of the components proceeds. The cavity portion (C) might possibly disappear during the mixing. Hence, it is preferable that the viscosity of the base resin and the curing agent is low in order to easily make the mixture uniform without the disappearance of the space (C₁), as described above. In particular, the greatest factor for the disappearance of the cavity portion (C) in this step includes the amount of the base resin mixed in Step 1. When the amount of the base resin mixed in Step 1 is smaller than the amount described in the above (Step 1), attachment easily occurs in Step 2. If such attachment occurs, the particles (B) are deformed, and thereby the space for forming the cavity portion (C) would disappear.

The mixing is preferably carried out in an ordinary environment of, for example, approximately 5 to 25° C., although the environment applied to the mixing operation is not limited, as long as the curing of a silicone resin composition does not proceed therein.

Moreover, the mixing operation in Step 2 is preferably conducted by a low-shear stirring method using a propeller blade, a paddle blade, an anchor blade, a Pfaudler blade, a helical ribbon blade, a plate blade, or the like, so that the space for forming the cavity portion (C) would not disappear.

### (Step 3)

Next, the resin-particle mixture obtained in Step 2 is disposed, for example, on a film, such that the thickness thereof becomes uniform. As the film, a film that can be easily released from a silicone resin foamed body is preferable, and it is specifically a PET film, although the film is not particularly limited. When such an easily releasable film is used, a silicone resin foamed body, the surface of which is flat, can be obtained by removing the film at the stage of completion of Step 4.

Moreover, in the present step, another film may be further disposed on the resin-particle mixture.

Furthermore, when the form of a final product is a laminated body of a silicone resin foamed body and a film, it may be adequate if at least one of the above films is not removed.

Examples of the method of disposing the resin-particle mixture on the film such that the thickness thereof becomes uniform include a two-roll molding method, a calendar roll molding method, a press molding method, and a mold ejection molding method. During this operation, the adjustment is carried out so that a high pressure is not applied to the resin-particle mixture in order to avoid the destruction of the particles (B) or a decrease in cells. For example, when the resin-particle mixture is extremely thinned, a two-roll molding method, in which two rolls are provided at multiple sites with a stepwise-narrowed clearance and the mixture is then successively passed from the side with a wider clearance to sheet the mixture, is applied.

In addition, in the present Step 3, instead of disposing a resin-particle mixture on a film, the resin-particle mixture may be disposed on a material other than the film. For example, the resin-particle mixture may be disposed on a belt made of a fluorine resin such as polytetrafluoroethylene, iron, stainless steel or the like. Otherwise, the resin-particle mixture may be disposed on an easily releasable plate material. When the resin-particle mixture is disposed on a belt, it becomes possible that the mixture is transported just as it is, for example, after curing.

### (Step 4)

In Step 4, the resin-particle mixture that has been disposed on the film or the other in the above Step 3 is heated to cure the silicone resin composition, resulting in obtaining a silicone resin foamed body. The heating temperature applied in this operation is preferably less than the melting temperature of the outer shell of each of the particles (B), and when the particles (B) have already been foamed, the heating temperature is preferably less than the temperature at which the particles were foamed. Thereby, a change in the shape or the particle diameter of each of the particles (B) can be prevented. The specific heating temperature is, for example, 20 to 120° C., and preferably 50 to 90° C.

With regard to the heating time, it is not necessary to heat the resin-particle mixture until the silicone resin is completely cured, and heating may be terminated when the film becomes in a state where it is capable of being released. It is to be noted that the curing reaction may proceed at room temperature even after termination of the heating.

In Step 4, the resin-particle mixture may be cured in a state in which it is wound around a paper tube or the like.

The obtained silicone resin foamed body is cooled if necessary, and it is released from a film or the like.

[Sealing Material]

The silicone resin foamed body of the present invention is preferably used as a sheet-shaped sealing material. The sealing material is disposed between members, and is used to seal a void generated between the members.

The sealing material of the present invention is used, for example, as a sealing material for a solar cell panel. In such a case, the sealing material is attached, for example, to the peripheral edge portion of the solar cell panel. The peripheral edge portion of the solar cell panel to which the sealing material is attached is inserted into a quadrangular frame, and the peripheral edge portion of the solar cell panel is thereby supported by the frame. The sealing material seals the gap between the solar cell panel and the frame, and prevents the intrusion of dusts, moisture and so on into the peripheral edge portion of the panel.

For the sealing material used for solar cell panel, the silicone resin foamed body may be used by a single body, but it may also be used in the form of a silicone resin foamed body, on one surface or both surfaces of which another layer is provided. For example, the sealing material used for solar cell panel may be a sealing material having the silicone resin foamed body on a surface of which a film (E) is laminated. In addition, the sealing material may also be a sealing material having the silicone resin foamed body on a surface of which a pressure- sensitive adhesive layer (F) is provided. In this case, the pressure-sensitive adhesive layer (F) may be directly laminated on the silicone resin foamed body, or it may also be laminated thereon via another layer such as a primer layer. Moreover, it may also be possible that the film (E) is provided on one surface of the silicone resin foamed body and the pressure-sensitive adhesive layer (F) is provided on the other surface thereof.

The film (E) is desirably integrated with the silicone resin foamed body by adhesion, fusion, or the like. In this case, a laminated body of the silicone resin foamed body and the film (E) is used as a sealing material.

The thickness of the film (E) is preferably 0.01 to 0.1 mm. By setting the thickness of the film to 0.01 mm or more, the dielectric breakdown voltage of the sealing material can be increased, and for example the insulation between the above solar cell panel and metallic frame can be ensured. In addition, by setting the thickness of the film to 0.01 mm or more, moisture permeability decreases, and as a result, watertightness can be enhanced. Moreover, by setting the thickness of the resin film to 0.1 mm or less, conformability to an uneven surface is good, and the sealing performance of the sealing material can be thus good.

The material of the film (E) is not particularly limited, but preferred examples thereof include polyolefin-based films such as PE (polyethylene) and PP (polypropylene) films, and polyester-based films such as a PET (polyethylene terephthalate) film.

From the viewpoint of the extensibility of the film (E), polyolefin-based films, particularly PE and PP films are desired. By using these films having extensibility for the film (E), when the silicone resin foamed body is provided on a periphery of a solar cell panel or the like, the silicone resin foamed body can be closely contacted therewith with applying tension, and therefore, the close-contact property with the solar cell panel is increased, and as a result, watertightness can be improved.

Also, the film (E) is preferably a PE film containing a stabilizer that has excellent weather resistance and light resistance.

The pressure-sensitive adhesive layer is formed, for example, by coating a surface of the silicone resin foamed body with a pressure-sensitive adhesive. As the pressure-sensitive adhesive, acrylic pressure-sensitive adhesive, urethane-based pressure-sensitive adhesive, rubber-based pressure-sensitive adhesive, silicone pressure-sensitive adhesive, and the like can be used, and acrylic pressure-sensitive adhesive is preferred. The pressure-sensitive adhesive layer is releasable, and can be released, for example, from an adherend or the like even after once adhering to the adherend.

As the primer constituting the primer layer, adhesion promoters for increasing the adhesiveness between the pressure-sensitive adhesive layer and the silicone resin foamed body, and the like can be used. Specific examples of commercial products of the adhesion promoters include P5200 from Dow Corning, and Primer T, Primer A-10, Primer R-3, Primer AQ-1 and Primer B-20 from Shin-Etsu Chemical Co., Ltd.

Moreover, as the film (E), a film which comprises the resin film and a releasing layer formed with a releasing agent such as a silicone-based releasing agent and a long-chain alkyl-based releasing agent that is provided on a surface opposite to the silicone resin foamed body side of the resin film, may be used. Thus, if a releasing layer is provided in such a way, when a laminated body of the foamed body and the film (E) is wound in the form of a roll, the releasing properties of the opposite surface of the film (E), for example, from the silicone resin foamed body, become good, and as a result, the above laminated body is easily unwound.

Furthermore, the film (E) may also be a releasing film that is not integrated with the silicone resin foamed body. The releasing film is generally removed from the silicone resin foamed body, when the silicone resin foamed body is used as a sealing material. A releasing treatment may be performed on a surface of the releasing film which contacts the silicone resin foamed body.

Examples of the releasing film include polyester-based films comprising, as a base material, a PET (polyethylene terephthalate) film, and polyolefin-based films comprising, as a base material, a PE (polyethylene) or PP (polypropylene) film or the like. From the viewpoint of the above extensibility, films comprising a polyolefin-based base material such as a PE (polyethylene) or PP (polypropylene) film are preferably used.

The silicone resin foamed body of the present invention is made of a foamed silicone and has weak tear strength, and therefore, the balance with the extension strength of the film (E) is important for the silicone resin foamed body on which the film (E) is laminated. For example, the tension at 5% extension of the silicone resin foamed body is preferably set to 15 to 50% of the tension at 5% extension of the film (E). By setting it to 15% or more, the tension is so large that the adhesiveness between the film (E) and the foamed body is satisfactory. In addition, by setting it to 50% or less, a laminated body of the foamed body and the film (E) can be prevented from tearing when it is unwound from a wound body and is brought in close contact with an object to be attached, or the like. In other words, by setting it in the above range, the laminated body of the film (E) and the foamed body can be closely contacted with an object to be attached (for example, a solar cell panel) with appropriate tension, and the above range is effective particularly when the silicone resin foamed body is brought in close contact therewith using automated equipment.

The tension at 5% extension herein refers to tension when a sample of width 25 mm×measured length 100 mm is extended by 5% in the length direction by a tensile tester, and the direction parallel to the MD direction of the releasing film in the sealing material for solar cell panel is taken as the extension direction.

It is to be noted that the silicone resin foamed body of the present invention can be used for intended uses other than solar cells, and that it can be used as a sealing material in mobile phones, or as a sealing material for vehicles such as automobiles and motorcycles. Moreover, the silicone resin foamed body of the present invention may also be used for intended uses other than a sealing material.

### EXAMPLES

The present invention will be described in more detail using Examples, but the present invention is not limited to these examples.

### [Measurement Methods]

Physical properties and performance were evaluated by methods as shown below.

### <Average Particle Diameter and Void Ratio of Particles (B)>

The average particle diameter and void ratio were calculated by the methods described in this specification using a microscope (manufactured by KEYENCE, model VH-Z series).

### <Foam Start Temperature and Maximum Foam Temperature>

The foam start temperature (Ts) and maximum foam temperature (Tmax) were measured using a thermomechanical analyzer (TMA) (TMA2940, manufactured by TA instruments). Specifically, 25 μg of a specimen was placed in a container made of aluminum having a diameter of 7 mm and a depth of 1 mm, and heated from 80° C. to 220° C. at a temperature increase rate of 5° C./min in a state in which a force of 0.1 N was applied from above, and the displacement of the measurement terminal in the vertical direction was measured. The temperature at which the displacement starts to rise was taken as the foam start temperature, the maximum value of the displacement was taken as the amount of maximum displacement, and the temperature at the amount of maximum displacement was taken as the maximum foam temperature.

### <Thickness>

The thickness was measured in a unit of up to 1 μm by a dial gauge.

### <Expansion Ratio and Closed Cell Ratio>

A test piece having a planar square shape having a side of 5 cm is cut from the silicone resin foamed body. The thickness of the test piece is measured, the apparent volume V₁ of the test piece is calculated, and the weight of the test piece W₁ is measured. The expansion ratio is calculated from the volume V₁ and the weight W₁ based on the following formula. In addition, the specific gravity is also calculated from the volume V₁ and the weight W₁.

Expansion ratio=V₁/W₁

Moreover, the apparent volume V₂ of the cells (i.e., the cavity portions (b1) and the cavity portions (C)) is calculated based on the following formula. The density of the resin constituting the test piece is taken as 1 g/cm³.

Apparent volume of the cells V₂=V₁−W₁

Next, the test piece is sunk in distilled water at 23° C. at a depth of 100 mm from the water surface, and a pressure of 15 kPa is applied to the test piece over 3 minutes. The pressure is released in the water, and then, the test piece is taken out from the water, moisture attached to the surface of the test piece is removed, the weight of the test piece W₂ is measured, and an open cell ratio F₁ and a closed cell ratio F₂ are calculated based on the following formulas.

Open cell ratio F₁(%)=100×(W₂−W₄)/V₂

Closed cell ratio F₂(%)=100−F₁

<Volume Ratio between Cavity Portion (b1) and Cavity Portion (C)>

First, the following procedures (A) and (B) are carried out.
(A) A foamed body is frozen with liquid nitrogen, so that it is in a condition of Tg or less. Thereafter, a section is sliced using a microtome.
(B) Subsequently, the sliced section is photographed by an electron microscope. Using the obtained photograph, a sum of the areas of void portions in hollow particles, the section of which has been sliced, is taken as S1₁, the area of the entire photograph is taken as S2₁, and S1₁ and S2₁ are detected.

Next, as with the above (A), 2 μm of a section is cut out using a microtome. Thereafter, after photographing in the same manner as the above (B), a sum of the areas of void portions in hollow particles is taken as S1₂, the area of the entire photograph is taken as S2₂, and S1₂ and S2₂ are detected. Likewise, 20 sections are photographed repeatedly, and S1₃, S1₄, . . . S1₂₀, S2₃, S2₄, . . . S2₂₀ are detected. Then, S1₁/S2₁, S1₂/S2₂, . . . S1₂₀/S2₂₀ are calculated. Thereafter, the average value S1/S2 of these S₁/S2₁ to S1₂₀/S2₂₀ is calculated.

Next, also using the above-mentioned apparent volumes V₁ and V₂, the volume ratio of the cavity portion (b1) in each of the particles (B) to another cavity portion (cavity portion (C)) is calculated based on the following formula.

Volume ratio of cavity portion (b1):cavity portion (C)=V₁×(S1/S2):V₂−V₄×(S1/S2)

<Compressive Strength>

The 20% and 50% compressive strengths of the silicone resin foamed body were measured according to JIS K6767. It is to be noted that, in the present invention, the measurement was carried out, after a plurality of silicone resin foamed bodies had been laminated on one another such that a total thickness of the silicone resin foamed bodies became 10 mm.

### Example 1

### (Making of Particles (B))

5 Parts by mass of thermally-expandable microcapsules (average particle diameter 16 μm, spherical, foam start temperature 122° C., maximum foam temperature 167° C., “ADVANCELL EML101” manufactured by SEKISUI CHEMICAL CO., LTD.) and 50 parts by mass of “TSE3032A” (viscosity (23° C.): 4.2 Pa·s), which was the base resin for a silicone resin (two-component heat-curable liquid silicone rubber) manufactured by Momentive Performance Materials Japan LLC., were mixed, using a planetary mixer, to obtain a mixture that is uniform. Then, the mixture was placed on a PET film and heated at 155° C. for 4 minutes to expand the thermally-expandable microcapsules to obtain a mixture containing particles (B) each having a cavity portion therein. The obtained mixture was apparently largely expanded, and a space was formed in the base resin between the particles (B).

### (Making of Resin-Particle Mixture)

Next, so as not to lose the above space in the base resin by filling it with a silicone resin composition, using a Pfaudler blade at a rotation rate of 50 rpm, 10.45 parts by mass of the mixture containing the particles (B), 2.5 parts by mass of “TSE3032A,” which was a base resin for a silicone resin manufactured by Momentive Performance Materials Japan LLC., and 1.2 parts by mass of “TSE3032B” (viscosity (23° C.): 0.7 Pa·s), which was a curing agent for the silicone resin, were mixed at ordinary temperature (23° C.) to obtain a resin-particle mixture composed of a silicone resin composition and particles (B). It is to be noted that 7.2 parts by mass of the thermally-expandable microcapsules were blended based on 100 parts by mass of the silicone resin composition in the resin-particle mixture.

### (Making of Silicone Resin Foamed Body)

The resin-particle mixture was quantitatively and continuously fed between two rolls with a clearance of 0.6 mm and spread between PET films (manufactured by Toray Industries Inc., Lumirror S, thickness 0.05 mm), and was then wound around a paper tube having an inner diameter of 6 inch, and was continuously heated at 90° C. for 30 minutes. At this time, it was considered that the curing reaction was not completed, but the heating was stopped because no problems would occur in subsequent handling. After being allowed to stand at ordinary temperature for 1 day, the PET films were released to obtain a sheet-shaped silicone resin foamed body.

In the silicone resin foamed body, the average particle diameter of the particles (B) was 80 μm, which was 5 times that of the thermally-expandable microcapsules before foaming. In addition, the void ratio of the particles (B) was 90.1%. Moreover, a cavity portion (C) was also found in sites other than the inside of each of the particles (B). Various physical properties of the silicone resin foamed body were measured. The results are shown in Table 2.

### Example 2

### (Making of Particles (B))

5 Parts by mass of thermally-expandable microcapsules (average particle diameter 16 μm, spherical, foam start temperature 122° C., maximum foam temperature 167° C., “ADVANCELL EML101” manufactured by SEKISUI CHEMICAL CO., LTD.) and 50 parts by mass of “TSE3032A” (viscosity (23° C.): 4.2 Pa·s), which was the base resin for a silicone resin (two-component heat-curable liquid silicone rubber) manufactured by Momentive Performance Materials Japan LLC., were mixed, using a three-roll mill to obtain a mixture that was uniform. Then, the mixture was placed on a PET film and heated at 155° C. for 4 minutes to expand the thermally-expandable microcapsules to obtain a mixture containing particles (B) each having a cavity portion therein. The obtained mixture was apparently largely expanded, and a space was formed in the base resin between the particles (B).

### (Making of Resin-Particle Mixture)

Next, so as not to lose the above space in the base resin by filling it with a silicone resin composition, using a Plast Mill, 8.8 parts by mass of the mixture containing the particles (B), 4 parts by mass of “TSE3032A,” which was the base resin for a silicone resin manufactured by Momentive Performance Materials Japan LLC., and 1.2 parts by mass of “TSE3032B” (viscosity (23° C.): 0.7 Pa·s), which was the curing agent for the silicone resin, were mixed at ordinary temperature (23° C.) to obtain a resin-particle mixture composed of a silicone resin composition and particles (B). It is to be noted that 6.1 parts by mass of the thermally-expandable microcapsules were blended based on 100 parts by mass of the silicone resin composition in the resin-particle mixture.

Thereafter, a silicone resin foamed body was obtained in the same manner as that of Example 1, with the exception that two rolls were provided at four sites, their clearance was stepwise narrowed to 1.0 mm, 0.6 mm, 0.3 mm and 0.2 mm, and the resin-particle mixture was successively fed thereto for sheeting.

In the silicone resin foamed body, the average particle diameter of the particles (B) was 80 μm, which was 5 times that of the thermally-expandable microcapsules before foaming. In addition, the void ratio of the particles (B) was 90.1%. Moreover, a cavity portion (C) was also found in sites other than the inside of each of the particles (B). Various physical properties of the silicone resin foamed body were measured. The results are shown in Table 2.

### Example 3

A resin-particle mixture composed of a silicone resin composition and particles (B) was obtained in the same manner as that of Example 1 with the exception that the amounts of components blended were changed as shown in Table 1. It is to be noted that 9.1 parts by mass of the thermally-expandable microcapsules were blended based on 100 parts by mass of the silicone resin composition in the resin-particle mixture.

Thereafter, a silicone resin foamed body was obtained by using the above resin-particle mixture in the same manner as that of Example 1 with the exception that the clearance between the two rolls was changed to 2.2 mm. In the silicone resin foamed body, the average particle diameter of the particles (B) was 80 μm, which was 5 times that of the thermally-expandable microcapsules before foaming. In addition, the void ratio of the particles (B) was 90.1%. Moreover, a cavity portion (C) was also found in sites other than the inside of each of the particles (B). Various physical properties of the silicone resin foamed body were measured. The results are shown in Table 2.

### Comparative Example 1

A resin-particle mixture was obtained in the same manner as that of Example 1 with the exception that the amounts of components blended were changed as shown in Table 1. It is to be noted that 5.3 parts by mass of the thermally-expandable microcapsules were blended based on 100 parts by mass of the silicone resin composition in the resin-particle mixture.

Thereafter, a silicone resin foamed body was obtained by using the above resin-particle mixture in the same manner as that of Example 1 with the exception that the clearance between the two rolls was changed to 0.65 mm.

In Comparative Example 1, the attachment of the particles (B) had already been seen in the step of making the particles (B), and it was assumed that, in the step of making the resin-particle mixture, the attachment would have further proceeded. As a result, a silicone resin foamed body having poor uniformity and insufficient formation of the cavity portion (C) was obtained. Various physical properties of the silicone resin foamed body were measured. The results are shown in Table 2.

### Comparative Example 2

A mixture containing particles (B) was obtained in the same manner as that of Example 1 with the exception that the amounts of components blended were changed as shown in Table 1.

Next, 7.7 parts by mass of the mixture containing the particles (B), 5.0 parts by mass of “TSE3032A,” which was a base resin, and 1.2 parts by mass of “TSE3032B,” which was a curing agent, were mixed at ordinary temperature (23° C.) to obtain a resin-particle mixture composed of a silicone resin composition and particles (B). It is to be noted that 3.0 parts by mass of the thermally-expandable microcapsules were blended based on 100 parts by mass of the silicone resin composition in the resin-particle mixture.

Thereafter, the resin-particle mixture was heated using a pressing machine at a pressure of 10 MPa at 50° C. for 3 hours to obtain a silicone resin foamed body. Since the ratio of the thermally-expandable microcapsules was small, a sufficient expansion ratio could not be obtained. Since the cavity portion (C) was also pushed out from the system using pressing, the volume ratio (b1:C) became small.

### Comparative Example 3

A mixture containing particles (B) was obtained in the same manner as that of Example 1 with the exception that the amounts of components blended were changed as shown in Table 1.

Next, 2.1 parts by mass of the mixture containing the particles (B), 10.6 parts by mass of “TSE3032A,” which was a base resin, and 1.2 parts by mass of “TSE3032B,” which was a curing agent, were mixed at ordinary temperature (23° C.) to obtain a resin-particle mixture composed of a silicone resin composition and particles (B). It is to be noted that 5.3 parts by mass of the thermally-expandable microcapsules were blended based on 100 parts by mass of the silicone resin composition in the resin-particle mixture.

Thereafter, a silicone resin foamed body was obtained by using the above resin-particle mixture in the same manner as that of Example 1 with the exception that the resin-particle mixture was fed between two rolls to make a bank, and that the clearance between the two rolls was changed to 0.3 mm. In the present Comparative Example 3, since the roll clearance was narrowed by a single step, the mixture was fed such that it was crushed between the rolls, and thus, the cavity portion (C) was not formed.

TABLE 1

| | | | | | Comparative | Comparative | Comparative |
|---|---|---|---|---|---|---|---|
| | | Example 1 | Example 2 | Example 3 | Example 1 | Example 2 | Example 3 |
| Mixture | Thermally-expandable | ADVANCELL | ADVANCELL | ADVANCELL | ADVANCELL | ADVANCELL | ADVANCELL |
| containing | microcapsules | EML101 | EML101 | EML101 | EML101 | EML101 | EML101 |
| particles | parts by mass | 5 | 5 | 5 | 5 | 5 | 5 |
| (B) | Base resin | TSE3032A | TSE3032A | TSE3032A | TSE3032A | TSE3032A | TSE3032A |
| | parts by mass | 50 | 50 | 50 | 2 | 50 | 10 |
| | Base | 10 | 10 | 10 | 0.4 | 10 | 2 |
| | resin/microcapsules | | | | | | |
| Resin | Mixture containing | 10.45 | 8.8 | 13.2 | 0.98 | 4.4 | 2.1 |
| particle | particles (B) | | | | | | |
| mixture | parts by mass | | | | | | |
| | Base resin | TSE3032A | TSE3032A | TSE3032A | TSE3032A | TSE3032A | TSE3032A |
| | parts by mass | 2.5 | 4 | 0 | 11.7 | 8 | 10.6 |
| | Curing agent | TSE3032B | TSE3032B | TSE3032B | TSE3032B | TSE3032B | TSE3032B |
| | parts by mass | 1.2 | 1.2 | 1.2 | 1.2 | 1.2 | 1.2 |

TABLE 2

| | Example | Example | Example | Comparative | Comparative | Comparative |
|---|---|---|---|---|---|---|
| | 1 | 2 | 3 | Example 1 | Example 2 | Example 3 |
| Thickness of foamed | 0.48 | 0.10 | 2.10 | 0.55 | 0.50 | 0.51 |
| body (mm) | | | | | | |
| Specific gravity of | 0.083 | 0.11 | 0.065 | 0.46 | 0.82 | 0.21 |
| foamed body (g/cc) | | | | | | |
| Expansion ratio of | 12 | 9 | 15 | 2.2 | 1.2 | 4.8 |
| foamed body (-fold) | | | | | | |
| Closed cell ratio (%) | 80 | 84 | 73 | 88 | 92 | 100 |
| of foamed body | | | | | | |
| Volume ratio (b1:C) | 1:1.7 | 1:1.4 | 1:2.4 | 1:0.15 | 1:0.015 | 1:0 |
| 20% Compressive stress | 0.09 | 0.12 | 0.07 | 0.21 | 0.24 | 0.19 |
| of foamed body (MPa) | | | | | | |
| 50% Compressive stress | 0.13 | 0.21 | 0.10 | 0.78 | 1.02 | 0.51 |
| of foamed body (MPa) | | | | | | |

As is clear from Table 2, since the volume of the cavity portion (C) could be increased in Examples 1 to 3, a high expansion ratio could be obtained although the thickness was small, and a foamed body having good 20% and 50% compressive stresses and also having excellent shock absorbency and sealing properties could be obtained. On the other hand, in Comparative Examples 1 to 3, the volume of the cavity portion (C) was small, and thus, a foamed body having a high expansion ratio could not be obtained. As a result, a compressive stress, and in particular, a 50% compressive stress became high, and a foamed body having excellent shock absorbency and sealing properties could not be obtained.

1. A silicone resin foamed body comprising: a silicone resin cured product (A) formed by curing a silicone resin composition; and a plurality of particles (B) dispersed in the silicone resin cured product (A) and each having a cavity portion (b1) therein, wherein
the silicone resin foamed body has a cavity portion (C) surrounded with the silicone resin cured product (A) or with the silicone resin cured product (A) and the particles (B) in the silicone resin cured product (A), and the volume ratio of the cavity portion (b1) to the cavity portion (C) is 2:1 to 1:4.

2. The silicone resin foamed body according to claim 1, which is obtained by curing a mixture comprising the silicone resin composition and the plurality of particles (B), a space around the particles (B) being present in the mixture, wherein the cavity portion (C) is formed by the space.

3. The silicone resin foamed body according to claim 1, wherein the cavity portion (C) is not formed using a chemical foaming agent.

4. The silicone resin foamed body according to claim 1, having a thickness of 0.05 to 2.5 mm and an expansion ratio of 7 cc/g or more.

5. The silicone resin foamed body according to claim 1, wherein the plurality of particles (B) comprise foamed particles that have been expanded.

6. A sealing material comprising: the silicone resin foamed body according to claim 1; and a film (E) and/or a pressure-sensitive adhesive layer (F) that are laminated on the silicone resin foamed body.

7. A method for manufacturing the silicone resin foamed body according to claim 1, comprising: a step of obtaining a mixture of particles (B) each having a cavity portion (b1) therein and a silicone resin composition, a space being present around the particles (B) in the mixture; and a step of curing the mixture to obtain a silicone resin foamed body.
